(19) United States
(12) Patent Application Publication
(10) Pub. No.: US 2025/0362255 A1
(43) Pub. Date: Nov. 27, 2025

(54) Charged Particle Beam System and Sample Evaluation Information Generation Method

(71) Applicant: Hitachi High-Tech Corporation, Minato-ku, Tokyo (JP)

(72) Inventors: Kazuhisa HASUMI, Tokyo (JP); Muneyuki FUKUDA, Tokyo (JP)

(21) Appl. No.: 18/874,151

(22) PCT Filed: Jun. 20, 2022
(86) PCT No.: PCT/JP2022/024510

§ 371 Date: Dec. 12, 2024

(51) Int. Cl. G01N 23/2251; H01L 21/66

(52) U.S. Cl. CPC G01N 23/2251; H01L 22/14; G01N 2223/6116

(57) ABSTRACT

According to the present disclosure, in order to enable evaluation of a semiconductor on the basis of characteristics that are equivalent to transistor (Tr) characteristics and are acquired in an earlier stage during a semiconductor manufacturing process, the amount of a signal from a drain is measured, the amount corresponding to the number of irradiations (where the amount of a single irradiation is determined in advance) by a charged particle beam irradiating a gate-corresponding part of a wafer of which the internal structure includes a Tr or a structure similar to a Tr. That is, the gate is continuously irradiated with the charged particle beam in a stepwise manner to render a Tr in ON state, and then the amount of signal obtained from the drain is measured each time the drain is irradiated with the charged particle beam. Then, the relationship between the number of irradiations of the gate with the charged particle beam and the corresponding amount of signal from the drain is generated, thereby making it possible to acquire characteristics equivalent to the relationship (Tr characteristics) between a gate voltage Vg and a source-drain current Ids of the Tr during the semiconductor manufacture process (see FIG. 6).

### DESCRIPTION

### Technical Field

The present disclosure relates to a charged particle beam system and a sample evaluation information generation method.

### Background Art

Regarding a semiconductor, a defect inspection of specifying a failure portion at a manufacturing stage is executed. For example, PTL 1 discloses that a pattern on a semiconductor wafer is irradiated with a beam to obtain a pattern image, characteristics of the pattern image are extracted, and a type of a defect is specified from the characteristics.

However, recently, it is desired that the defect inspection is executed during a semiconductor manufacturing process to improve the efficiency of semiconductor manufacturing. From this point of view, regarding the failure portion specifying during the semiconductor manufacturing process, for example, PTL 2 discloses that a semiconductor device during the semiconductor manufacturing process is irradiated with an electron beam multiple times at a predetermined interval, generated secondary electrons are detected to form an electron beam image, and a junction leakage failure portion is specified based on a signal level of the image. In addition, PTL 3 discloses that, regarding inspection of a material, a structure, or the like in a sample in a cross-sectional direction (depth direction), analysis in the depth direction is executed with low damage. In PTLs 2 and 3, in order to execute the analysis of the internal structure such as a resistor, a capacitor, or a junction leakage, a signal amount representing characteristics is detected as a defect. For example, a failure portion is specified by calculating a signal amount of an image in response to an input of an electron beam and comparing the calculated signal amount to an image or a signal amount during a normal time to execute the inspection.

On the other hand, transistor (hereinafter, also referred to as Tr) characteristics of a semiconductor generally form a saturation curve, refer to response characteristics (Vg-Ids curve) of a source-drain current Ids with respect to a gate voltage Vg, and can be used as an index representing the performance of Tr. That is, by using the transistor characteristics, whether a defect is present in TR can be evaluated. The transistor characteristics are acquired by measuring electrical characteristics by probing in a process after patterning a PAD in a wiring process during semiconductor manufacturing or in a final process of semiconductor manufacturing.

### CITATION LIST

### Patent Literature

PTL 3: JP2021-27212A

PTL 1: JP2002-09121A

PTL 2: JP6379018B

### SUMMARY OF INVENTION

### Technical Problem

In the related art, the transistor characteristics can be acquired only in the wiring process or in the final process of semiconductor manufacturing. However, during semiconductor manufacturing having a large number of processes, it is desired that the transistor characteristics are acquired to be used for a non-destructive inspection even before the wiring process. The reason for this is that, if a failure of a semiconductor can be inspected at an earlier stage, the semiconductor can be efficiently manufactured.

On the other hand, in PTLs 2 and 3 described above, the internal structure such as a resistor, a capacitor, or a junction leakage in a wafer during the semiconductor manufacturing process is irradiated with an electron beam to obtain an electron microscope image (single image acquisition), and a signal amount is calculated from the electron microscope image such that inspection or analysis can be executed.

However, the techniques of PTLs 2 and 3 do not relate to the acquisition of the above-described transistor characteristics, and cannot satisfy the demands for utilizing the Tr characteristics at an early stage of the semiconductor manufacturing process.

Under these circumstances, the present disclosure proposes a technique capable of acquiring transistor characteristics at an earlier stage during a semiconductor manufacturing process to evaluate a semiconductor based on the transistor characteristics.

### Solution to Problem

In order to achieve the above-described object, the present disclosure proposes, for example, a charged particle beam system including: a charged particle beam device configured to irradiate a sample with a charged particle beam to acquire a signal from the sample; and a computer system configured to control an operation of the charged particle beam device, in which the sample is a wafer in a process during a semiconductor manufacturing process, the wafer having an internal structure where a transistor or a structure similar to a transistor is provided, and the computer system executes (i) a process of setting given information to the charged particle beam device, the given information including at least information regarding the number of times a gate and a drain of the internal structure are irradiated with the charged particle beam and information regarding an irradiation position of the charged particle beam, (ii) a process of controlling the charged particle beam device to execute irradiation of the gate with a first charged particle beam and irradiation of the drain with a second charged particle beam that is the same as or different from the first charged particle beam and acquiring information regarding a signal amount obtained from the drain by the irradiation of the second charged particle beam, a process of generating a first electrical characteristic representing a relationship of the signal amount obtained from the drain corresponding to the number of times the gate is irradiated with the first charged particle beam, and a process of outputting the first electrical characteristic.

Further characteristics related to the present disclosure will be clarified from the description of the present specification and the accompanying drawing. In addition, aspects of the present disclosure can be achieved and implemented by elements, a combination of multiple elements, the following detailed description and the scope of the appended claims.

The description of the present specification is merely a typical example and does not limit the claims or application examples of the present disclosure by any means.

### Advantageous Effects of Invention

According to the technique of the present disclosure, transistor characteristics can be acquired at an earlier stage during a semiconductor manufacturing process to evaluate a semiconductor based on the transistor characteristics.

### BRIEF DESCRIPTION OF DRAWINGS

FIG. 1 is a diagram illustrating a SEM image 101 having an internal structure where a Tr or a structure similar to a Tr (also referred to as a virtual Tr) is provided in an intermediate process of semiconductor manufacturing.

FIG. 2 is a diagram illustrating an internal structure 201 of the SEM image 101.

FIG. 3 is a diagram illustrating a cross-sectional structure 301 taken along line a-a of the internal structure illustrated in FIG. 2.

FIG. 4 is a diagram illustrating an equivalent circuit 401 of FIGS. 2 and 3.

FIG. 5 is a diagram illustrating Vg-Ids characteristics 501 that are a result of measurement.

FIG. 6 is a schematic diagram illustrating a brightness change example of each of holes based on the SEM image 101.

FIG. 7 is a diagram illustrating a relationship (characteristics) 701 between the number of times (horizontal axis) of irradiation of a gate hole 603 with an electron beam and a signal amount (vertical axis) obtained from a drain hole 604.

FIG. 8 is a diagram illustrating a schematic configuration example of a SEM system 801 according to a first embodiment.

FIG. 9 is a flowchart illustrating a process (electrical characteristic measurement process) of acquiring a curve equivalent to electrical characteristics (Vg-Ids characteristics).

FIG. 10 is a diagram illustrating gate hole irradiation number of times-drain hole signal amount characteristics.

FIG. 11 is a flowchart illustrating an electrical characteristic measurement process according to a second embodiment.

FIG. 12 is a diagram illustrating a schematic configuration example of a scanning electron microscope with a nanoprobe (SEM with a nanoprobe) 1200 according to a third embodiment.

FIG. 13 is a diagram illustrating a relationship between a potential applied from a nanoprobe 1201 to the gate hole 603 and a signal amount obtained from the drain hole (nanoprobe potential-drain hole signal amount characteristics).

FIG. 14 is a diagram illustrating a configuration example of a scanning electron microscope (SEM) 1400 including a sub-electron optical system 1401 according to a fourth embodiment.

FIG. 15 is a flowchart illustrating an electrical characteristic measurement process according to a sixth embodiment.

### DESCRIPTION OF EMBODIMENTS

An embodiment of the present disclosure discloses measurement of a signal amount obtained from a drain corresponding to the number of times of irradiation (a single irradiation amount is predetermined) of a portion with a charged particle beam (for example, an electron beam or an ion beam), the portion corresponding to a gate in a wafer (a state where a semiconductor is not yet completely manufactured) having an internal structure where a Tr or a structure similar to a Tr is provided. That is, by continuously irradiating the gate with the charged particle beam stepwise, the Tr enters an ON (GATE/ON) state, and subsequently a signal amount obtained from the drain is measured whenever the drain is irradiated with the charged particle beam. By generating a relationship between the signal amount obtained from the drain corresponding to the number of times of the irradiation of the gate with the charged particle beam, electrical characteristics corresponding to a relationship (transistor characteristics) between a gate voltage Vg and a source-drain current Ids in the Tr can be acquired during the semiconductor manufacturing process. Typically, an electrical characteristic inspection process of measuring the Tr characteristics needs to be suspended until a wiring process in semiconductor manufacturing, and a period of time is required. However, in the present embodiment, the wafer can be evaluated at an early stage of the semiconductor manufacturing process.

Hereinafter, embodiments and each of examples of the present disclosure will be described with reference to the accompanying drawings. In the accompanying drawings, functionally the same elements may also be represented by the same reference numerals. The accompanying drawings illustrate specific embodiments and implementations based on the principle of the present disclosure. These drawings are examples for easy understanding of the present disclosure and are not used to limit the present invention.

In the present embodiment, the present disclosure is described in detail sufficient for a person skilled in the art to implement the present disclosure, but other embodiments and configurations can also be adopted. It should be understood that changes of configurations and structures and replacement of various elements can be made within a range not departing from the scope and concepts of the technical idea of the present disclosure. Accordingly, the following description should not be interpreted as being limited to the present disclosure.

### <History of Conceiving Ideas>

When a pattern of a sample having an internal structure is observed with a scanning electron microscope (hereinafter, abbreviated as SEM), there is an event where the brightness of an image acquired with the SEM changes over time (within a short period of time of several seconds). When an insulator such as an oxide film was observed as a background and the pattern itself changed in brightness, the present inventors verified whether the change in brightness occurs due to another factor other than a known phenomenon in which the brightness changes due to a surface charging phenomenon caused by irradiation with an electron beam (or an ion beam). As a result, the present inventors noticed that, when a pattern at a position different from a location to be observed is irradiated with an electron beam and then a pattern at the position to be observed is observed again, the brightness changed. The present inventors found that this change in brightness occurs due to a phenomenon (for example, a response reaction of a semiconductor device) caused by ON/OFF of a Tr or a structure similar to a Tr in an internal structure, focused on this phenomenon, and thought about the use thereof.

### <Example of Internal Structure Where Tr or Structure Similar to Tr is Provided>

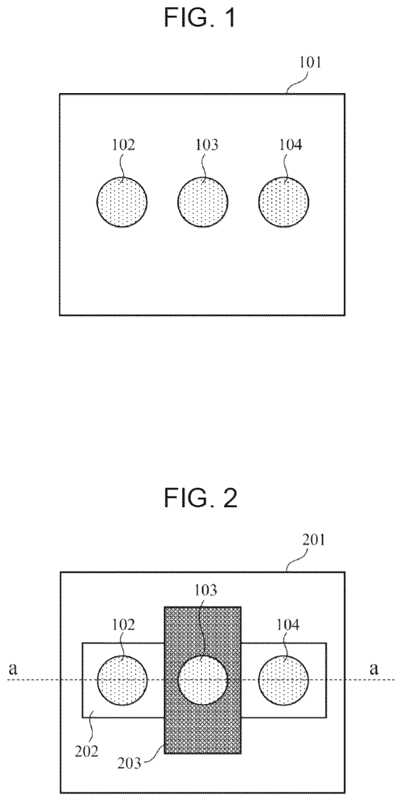

FIG. 1 is a diagram illustrating a SEM image 101 having an internal structure where a Tr or a structure (also referred to as a virtual Tr) similar to a Tr is provided in an intermediate process of semiconductor manufacturing. In FIG. 1, a case where three contact holes including a contact hole 102 connected to a source, a contact hole 103 connected to a gate, and a contact hole 104 connected to a drain are observed is assumed.

FIG. 2 is a diagram illustrating the internal structure 201 of the SEM image 101. The internal structure 201 corresponds to the SEM image 101, and a positional relationship between a Si substrate area 202 and a gate electrode 203 functioning as the source and the drain of the Tr, that is, a layout is illustrated. The internal structure at a stage where evaluation is executed needs to have a Tr or a structure similar to a Tr. That is, even in the intermediate process of semiconductor manufacturing, a Tr or a structure similar to a Tr needs to be formed.

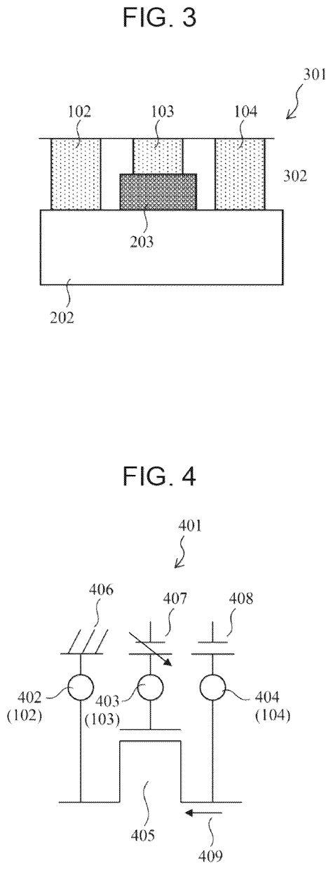

FIG. 3 is a diagram illustrating a cross-sectional structure 301 taken along line a-a of the internal structure illustrated in FIG. 2. As illustrated in FIG. 3, in an intermediate process of the semiconductor manufacturing, the contact hole 102 functioning as the source of the Tr, the gate electrode 203, the contact hole 103 connected to the gate electrode 203, and the contact hole 104 functioning as the drain of the Tr are formed on the Si substrate area 202.

FIG. 4 is a diagram illustrating an equivalent circuit 401 of FIGS. 2 and 3. The equivalent circuit can be a MOS transistor 405 including a source 402 (corresponding to 102) connected to a GND (ground) 406, a drain 404 (corresponding to 104) to which a fixed voltage 408 is applied, and a gate 403 (corresponding to 103). When electrical characteristics of the MOS transistor 405 are measured, a voltage (hereinafter, the gate voltage is abbreviated as Vg) is gradually applied to the gate 403, and a current flowing between the drain and the source corresponding to the voltage (hereinafter, drain-source current Ids 409) is measured.

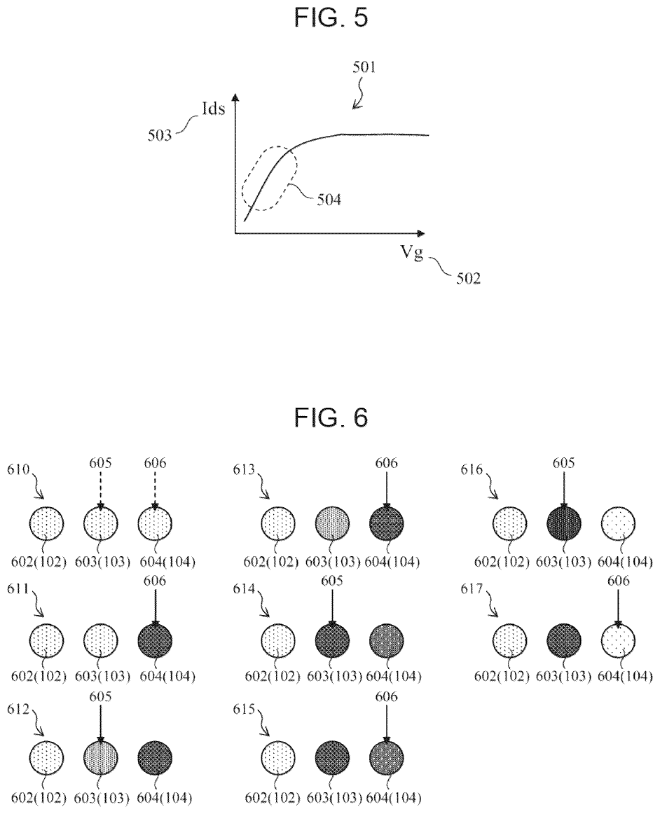

FIG. 5 is a diagram illustrating Vg-Ids characteristics 501 that are a result of measurement. The Vg-Ids characteristics 501 are a graph obtained by plotting a value of Ids with respect to Vg when the horizontal axis represents the gate voltage Vg 502 and the vertical axis represents the drain-source current Ids 503. Based on the Vg-Ids characteristics (Tr characteristics) 501, whether the Tr as a measurement target is normal can be evaluated. The Vg-Ids characteristics 501 are characteristics obtained when a semiconductor at a final stage (completed semiconductor) is measured, and thus cannot be derived during the semiconductor manufacturing process. Accordingly, hereinafter, acquisition of electrical characteristics corresponding to the Tr characteristics during the semiconductor manufacturing process will be described.

### <Acquisition of Characteristics Corresponding to Vg-Ids Characteristics (Tr Characteristics) by SEM)

Using FIG. 6, a method of acquiring the electrical characteristics corresponding to the Vg-Ids characteristics by irradiating the Tr or the structure similar to the Tr with an electron beam using a SEM will be described. FIG. 6 is a schematic diagram illustrating a brightness change example of each of the holes based on the SEM image 101. In FIG. 6, a transistor Tr including a contact hole (hereinafter, referred to as a source hole) 602 connected to a source, a contact hole (hereinafter, referred to as a gate hole) 603 connected to a gate, and a contact hole (hereinafter, referred to as a drain hole) 604 connected to a drain is assumed. In addition, the source hole 602 is connected to the GND or a substrate. In each of processes 610 to 617, the gate hole 603 and the drain hole 604 are irradiated with an electron beam multiple times. The electron beam with which the gate hole 603 is irradiated and the electron beam with which the drain hole 604 is irradiated may be the same (the intensities and the like are the same) as or different from each other. In addition, the electron beam irradiation is controlled by a computer. The same applies to each of embodiments described below. Hereinafter, it is assumed that the gate hole 603 is irradiated with a first electron beam and the drain hole 604 is irradiated with a second electron beam, that is, the gate hole 603 and the drain hole 604 are irradiated with different electron beams.

### (i) Stage 610 Before Electron Beam Irradiation

At this stage, all of the contact holes are not charged. Therefore, a clear image is obtained from each of the holes.

(ii) Stage 611 of Irradiation of Drain Hole 604 with Preliminary Electron Beam

At this stage, the drain hole 604 is irradiated with a preliminary electron beam (that may be an electron beam having the same properties (intensity and the like) as or having different properties from the first or the second electron beam) 606′, and the drain hole 604 is charged (the intensity and the irradiation time of the electron beam are controlled). The drain hole 604 is not connected to the GND, and thus when charging progresses, the obtained image becomes darker. In the present embodiment, a signal obtained in response to the electron beam irradiation when the drain hole 604 is charged as much as possible is set to a signal amount (brightness value) where the number of times of the irradiation of the gate hole 603 is 0 (initial state).

(iii) Stage 612 of First Irradiation of Gate Hole 603 with First Electron Beam

At this stage, the gate hole 603 is firstly irradiated with a first electron beam 605 for a predetermined time (at a predetermined irradiation amount), and the gate hole 603 is charged. At this time, the image obtained from the gate hole 603 becomes darker due to the influence of charging. Note that, since the gate is not sufficiently charged for changing the gate of the Tr of the internal structure into ON (hereinafter, referred to as GATE/ON), the gate is maintained in the OFF state. That is, at this stage, the irradiation of the first electron beam 605 is controlled such that the charge of the gate hole 603 does not reach a potential (gate voltage Vg) for changing the gate into ON. The reason for this is that, when the gate is charged at once and the gate is turned ON, characteristics of a rising portion (rising portion 504 of FIG. 5) of the Tr characteristics cannot be measured. By setting the number of times of the irradiation of the electron beam to be large until the GATE/ON state, the characteristics of the rising portion 504 of the Tr characteristics can be described in detail.

(iv) Stage 613 of First Irradiation of Drain Hole 604 with Second Electron Beam

At this stage, the drain hole 604 is firstly irradiated with the second electron beam 606. The irradiation of the second electron beam 606 is irradiation for achieving the image (brightness value) of the drain hole 604.

At a preliminary electron beam irradiation stage 611, the drain hole 604 is charged as much as possible such that the gate is in the OFF state. Therefore, the potential of the drain hole 604 does not flow to the source of the Tr, and the brightness value does not change (remains dark). At this time, the signal amount of a signal obtained in response to the irradiation of the second electron beam 606 is set to a signal amount (brightness value) where the number of times of the irradiation of the drain hole 604 is 1.

(v) Stage 614 of Second Irradiation of Gate Hole 603 with First Electron Beam

At this stage, the charging of the gate hole 603 further progresses due to the second irradiation of the first electron beam 605, and the image becomes darker. The gate of the Tr of the internal structure is changed to ON (GATE/ON), the potential of the drain hole 604 flows out to the source of the internal structure, and the image (brightness value) becomes brighter (higher).

(vi) Stage 615 of Second Irradiation of Drain Hole 604 with Second Electron Beam

At this stage, the drain hole 604 is secondly irradiated with the second electron beam 606. The irradiation of the second electron beam 606 is irradiation for achieving the image (brightness value) of the drain hole 604. At this time, the Tr of the internal structure is in the GATE/ON state. Accordingly, the potential remaining in the drain hole 604 flows out to the source of the Tr of the internal structure such that the signal amount (brightness value) decreases. Therefore, the image (brightness value) of the drain hole 604 is brighter (higher) than that in the state of the stage 613.

(vii) Stage 616 of Third Irradiation of Gate Hole 603 with First Electron Beam

At this stage, the third irradiation of the gate hole 603 with the first electron beam 605 is executed, the charging of the gate hole 603 further progresses, and the image becomes darker.

At this time, the Tr of the internal structure is continuously maintained in the GATE/ON state. Therefore, the remaining potential continuously flows to the source of the Tr of the internal structure (the charge further decreases, and the signal amount also decreases), and the image (brightness) of the drain hole 604 becomes brighter.

(viii) Stage 617 of Third Irradiation of Drain Hole 604 with Second Electron Beam

At this stage, the third irradiation of the drain hole 604 with the second electron beam 606 is executed. The irradiation of the second electron beam 606 is irradiation for achieving the image (brightness value) of the drain hole 604 as in the stage 613 and the stage 615.

At this time, the Tr of the internal structure is in the state where GATE/ON is continued. Therefore, all the potential remaining in the drain hole 604 flows out to the source of the Tr of the internal structure, and the signal amount (brightness value) of the drain hole 604 is the same as the brightness value of the source hole 602.

### (ix) Others

In the process of FIG. 6, the number of times of the irradiation of the gate hole 603 with the first electron beam and the number of times (number of repetitions) of the irradiation of the drain hole 604 with the second electron beam are three, respectively. The number of times of the irradiation can be set as a parameter by an operator (user).

In addition, here, the signal amount is the brightness value. Not only the detected brightness value but also the number of photons or the amount of secondary electrons generated from an electron beam irradiation portion that is information at a stage prior to imaging may be used as the signal amount.

<Relationship Between Number of Times of Irradiation of Gate Hole with Electron Beam and Signal Amount Obtained from Drain Hole>

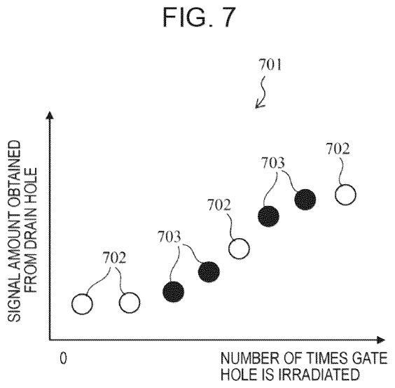

FIG. 7 is a diagram illustrating a relationship (electrical characteristics) 701 between the number of times (horizontal axis) of irradiation of the gate hole 603 with the electron beam and the signal amount (vertical axis) obtained from the drain hole 604. FIG. 7 illustrates cases where the number of times of the irradiation with the electron beam is 0 to 3. However, the number of times of the irradiation depends on the single irradiation amount of the electron beam. Accordingly, by reducing the irradiation amount at which the gate hole 603 is irradiated once with the electron beam, the number of times of the irradiation can be set to be large.

By setting the number of times of the irradiation (the total number of a plot 702 and a plot 703) to be plural (for example, 7) as illustrated in FIG. 7, a curve (curve equivalent to the characteristics 501) corresponding to the Vg-Ids characteristics 501 of the Tr illustrated in FIG. 5 is obtained. That is, by setting the number of times of the irradiation to be large as described above, characteristics of a rising portion 505 can be achieved in detail.

As described above, by irradiating the contact holes of the Tr or the structure similar to the Tr in the internal structure with the electron beam, the curve (graph) equivalent to the electrical characteristics (Vg-Ids characteristics) when the gate of the Tr is changed from OFF to ON can be acquired using the SEM. As a result, by converting the number of times of the irradiation (the number of repetitions) into the gate voltage Vg and converting the signal amount (change in brightness) obtained from the drain hole into the drain-source current Ids, the Tr or the structure similar to the Tr in the internal structure can be evaluated (whether a defect is present can be verified).

### (1) First Embodiment

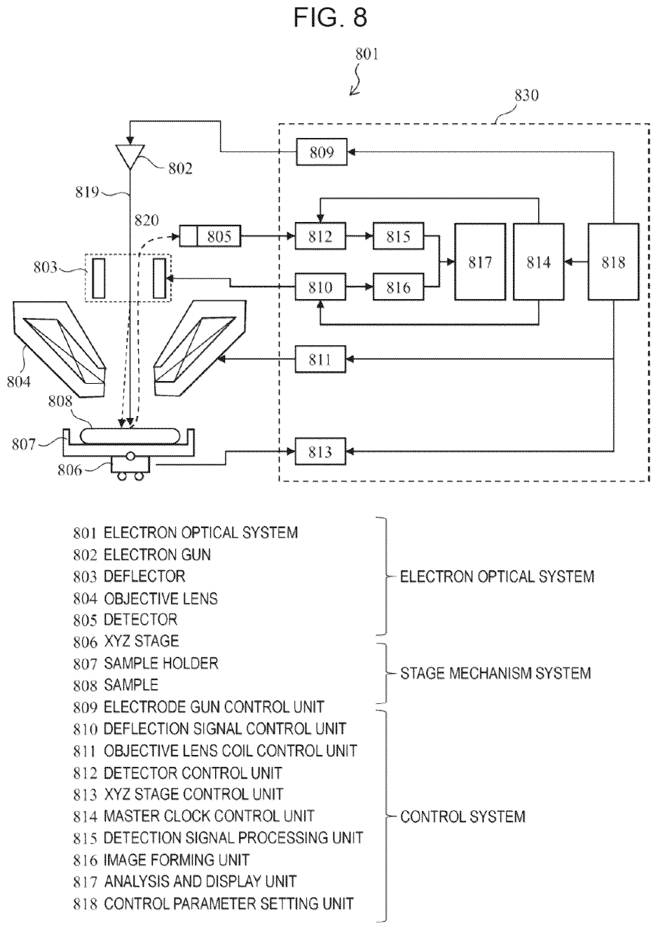

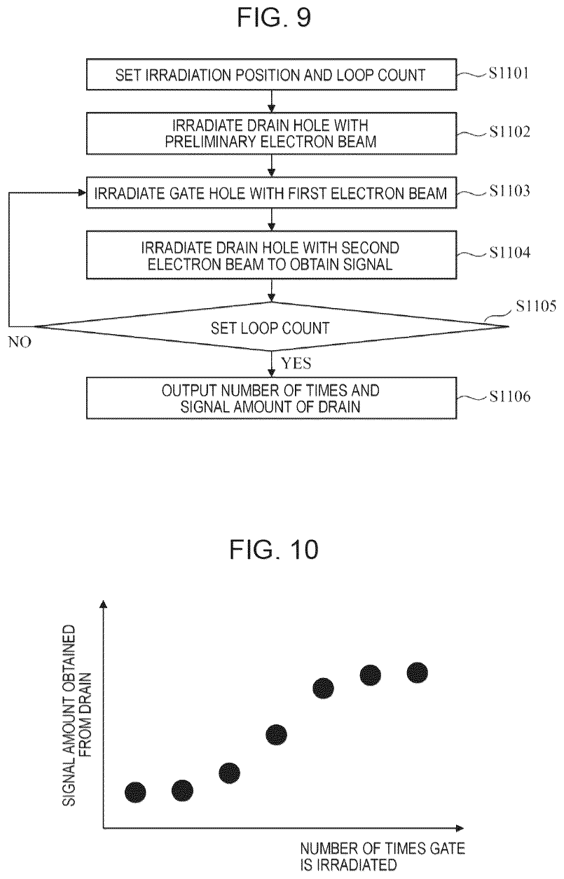

A first embodiment will be described with reference to FIGS. 8 and 9. In the first embodiment, the measurement using a scanning electron microscope system (SEM system) that is one charged particle beam system used for the measurement will be described.

### <Configuration Example of SEM System>

FIG. 8 is a diagram illustrating a schematic configuration example of a SEM system 801 according to the first embodiment. The SEM system 801 is configured with an electron optical system, a stage mechanism system, a control system, an image processing system, and an operation system.

The electron optical system includes an electron gun 802, a deflector 803, an objective lens 804, and a detector 805. Voltage application means for applying a voltage to a sample 808 can be connected to a sample holder 807.

The stage mechanism system includes an XYZ stage 806.

The control system includes an electron gun control unit 809, a deflection signal control unit 810, an objective lens coil control unit 811, a detector control unit 812, an XYZ stage control unit 813, and a master clock control unit 814 that synchronizes the time of the deflection signal control unit 810 and the time of the detector control unit 812.

The image processing system includes a detection signal processing unit 815 and an image forming unit 816.

The operation system includes a detection signal processing unit 815, an analysis and display unit 817 including a display unit that displays a result of analysis by the image forming unit 816, and a control parameter setting and overall control unit 818 of a control system that includes an operation interface and controls the entire system.

An electron beam 819 that is accelerated by the electron gun 802 is focused by the objective lens 804, and the sample 808 is irradiated with the focused electron beam 819. An irradiation position on the sample 808 is adjusted by the deflection signal control unit 810 controlling the deflector 803. Secondary electrons 820 emitted from the sample 808 are affected by an electric field on the sample, and are induced and detected by the detector 805.

In addition, the control system (the electron gun control unit 809, the deflection signal control unit 810, the objective lens coil control unit 811, the detector control unit 812, the XYZ stage control unit 813, and the master clock control unit 814), the image processing system (the detection signal processing unit 815 and the image forming unit 816), and the operation system (the detection signal processing unit 815, the analysis and display unit 817, and the control parameter setting and overall control unit 818) can be configured to be integrated or distributed by one or more computer systems 830 (in FIG. 8, the configuration is configured by one computer system 830).

### <Details of Electrical Characteristic Measurement Process>

FIG. 9 is a flowchart illustrating a process (electrical characteristic measurement process) of acquiring a curve equivalent to the electrical characteristics (Vg-Ids characteristics) 501. In the electrical characteristic measurement process by the flowchart of FIG. 9, a state where the brightness of each of the holes in the SEM image of FIG. 6 changes is used as an example. In the following description, an operation subject of the process in each of the steps is the corresponding processing unit (for example, the control parameter setting and overall control unit 818 or the deflection signal control unit 810). However, comprehensively, the computer system 830 may be the operation subject.

### (i) S101

When the operator inputs parameters for the measurement using an input device (not illustrated), the control parameter setting and overall control unit 818 sets (notifies) a loop count (the number of times of the irradiation of the electron beam), the irradiation time of the electron beam/irradiation (the irradiation timing of each of the electron beams), and the intensity (SEM basic condition: an acceleration voltage, a probe current, or the like of the electron beam with which the sample 808 is irradiated) of the electron beam with which each of the holes is irradiated to the electron gun control unit 809, sets (notifies) information regarding the irradiation position of the electron beam (pattern position of the gate hole 603 or the drain hole 604) to the objective lens coil control unit 811 and the XYZ stage control unit 813, and sets (notifies) the loop count and the irradiation time of the electron beam/irradiation (the irradiation timing of each of the electron beams) to the master clock control unit 814.

Here, the operator sets and inputs the irradiation position of the electron beam as the parameter, but the present disclosure is not limited thereto. For example, in order to determine the irradiation position of the electron beam, the computer system 830 may import CAD data to automatically designate coordinates (irradiation position) based on the CAD data. In the measurement process of the semiconductor manufacturing process, the internal structure cannot be recognized from the SEM image of the process. Therefore, by narrowing down the pattern position based on the CAD data including layout information and linking the coordinates, the measurement pattern position can be accurately designated.

### (ii) S102

When the placement of the sample (wafer) 808 on the sample holder 807 is verified, the XYZ stage control unit 813 moves the XYZ stage 806 for the preliminary electron beam irradiation, and roughly controls the position relative to the drain hole 604. While the electron gun 802 emits the preliminary electron beam, the deflection signal control unit 810 controls the deflector 803 to irradiate the position (accurate position) of the drain hole 604 designated by the parameter with the preliminary electron beam. This preliminary electron beam is irradiated, for example, until the drain hole 604 is charged as much as possible (darkest state). This state is the initial state (0 times) (refer to the stage 611 of FIG. 6).

(iii) S103

Optionally, the XYZ stage control unit 813 moves the XYZ stage 806 based on the position of the gate hole 603, and roughly controls the position relative to the gate hole 603. While the electron gun 802 emits the first electron beam, the deflection signal control unit 810 controls the deflector 803 to irradiate the position (accurate position) of the gate hole 603 designated by the parameter with the first electron beam. The gate hole 603 is charged due to the irradiation of the first electron beam, the image becomes darker. However, the gate hole 603 is not charged until the gate is changed to ON (GATE/ON). This state is the state after the first irradiation of the first electron beam (refer to the stage 612 of FIG. 6).

The loop count is configured with the number of times of the irradiation of the electron beam until GATE/ON+the number of times of the irradiation of the electron beam after GATE/ON. It can be said that, when the loop count increases, the charge amount of the contact hole by the single irradiation of the electron beam decreases.

### (iv) S104

Optionally, the XYZ stage control unit 813 moves the XYZ stage 806 again based on the position of the drain hole 604, and roughly controls the position relative to the drain hole 604. While the electron gun 802 emits the second electron beam, the deflection signal control unit 810 controls the deflector 803 to irradiate the position (accurate position) of the drain hole 604 designated by the parameter with the second electron beam. The drain hole 604 is further charged due to the irradiation of the second electron beam, and the image becomes darker. At this stage, the gate is not in the ON (GATE/ON) state. Therefore, the potential of the drain hole 604 does not flow out to the source of the Tr of the internal structure. This state is the state after the first irradiation of the second electron beam (refer to the stage 613 of FIG. 6).

### (v) S105

The control parameter setting and overall control unit 818 determines whether the irradiation of the first and second electron beams is executed by the set loop count. When the irradiation of the electron beams by the set loop count is completed (Yes in S105), the process proceeds to S106. When the irradiation of the electron beams by the set loop count is not completed (No in S105), the process proceeds (returns) to S103, and the processes of S103 and S104 are repeated until the loop count is reached. That is, the gate hole 603 and the drain hole 604 are irradiated with the first electron beam and the second electron beam until the Tr or the structure similar to the Tr in the internal structure enters the GATE/ON state and the state of the drain hole 604 reaches the stage 617 from the stage 614 of FIG. 6.

### (vi) S106

The control parameter setting and overall control unit 818 generates gate hole irradiation number of times-drain hole signal amount characteristics illustrated in FIG. 10 based on the signal amount of the drain hole 604 per irradiation of the gate hole 603 with the first electron beam. That is, the control parameter setting and overall control unit 818 generates change characteristics of the signal amount (gate hole irradiation number of times-drain hole signal amount characteristics) by plotting the signal amount per irradiation when the horizontal axis represents the number of times of the irradiation of the gate hole 603 with the first electron beam and the vertical axis represents the signal amount obtained from the drain hole 604 per irradiation.

### <Technical Effect of First Embodiment>

For example, in the semiconductor manufacturing process, by measuring each of a plurality of wafers using the method according to the first embodiment while experimentally changing conditions that affect the Tr characteristics, the change characteristics (gate hole irradiation number of times-drain hole signal amount characteristics) illustrated in FIG. 10 can be acquired for each of the wafers. By shifting each of the change characteristics to the right or the left, the level difference under each of the conditions can be verified. In addition, the level difference under each of the conditions can be verified based on the magnitude of the signal amount of each of the change characteristics.

In the first embodiment, the Tr is used as the example. However, the technique of the present disclosure is applicable to general semiconductor elements that becomes conductive or non-conductive by applying the potential. In addition, in the first embodiment, the contact holes (hole process) are used as the measurement pattern. However, the technique of the present disclosure is also applicable to a state of a diffusion layer pattern corresponding to a gate wiring and a source or a drain before the formation of the contact holes or to a wiring pattern after the formation of the contact holes.

### (2) Second Embodiment

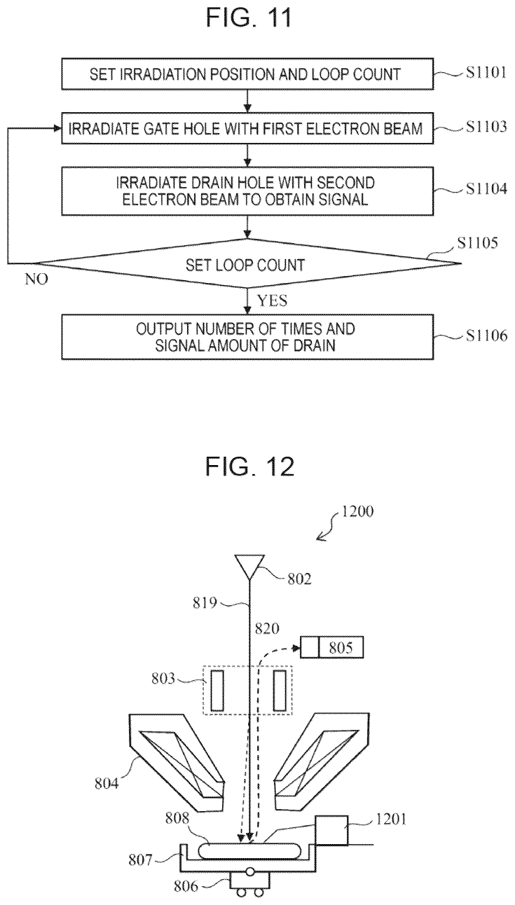

In the first embodiment, while charging the drain hole 604 (refer to FIG. 6), the Tr is changed to the ON state (GATE/ON state) to grasp the change in signal amount in the drain hole 604. However, in a second embodiment, a method of measuring a semiconductor element that becomes non-conducive by changing the Tr to the ON state will be described. In the semiconductor element, when the Tr is changed to the ON state and the drain hole 604 is irradiated with the electron beam, the signal amount measured from the drain hole 604 decreases contrary to the first embodiment. In the semiconductor element, as illustrated in FIG. 11 (flowchart illustrating an electrical characteristic measurement process according to the second embodiment), the step (S102) of irradiating the drain hole 604 with the preliminary electron beam is skipped, and the electrical characteristic measurement process is executed.

### (3) Third Embodiment

In the first and second embodiments, the Tr is changed to the ON state (GATE/ON state) by irradiating the gate hole 603 with the first electron beam for charging and increasing the potential of the gate hole 603. On the other hand, in a third embodiment, the Tr is changed to the ON state (GATE/ON state) to execute the electrical characteristic measurement process using a scanning electron microscope with a nanoprobe.

FIG. 12 is a diagram illustrating a schematic configuration example of a scanning electron microscope with a nanoprobe (SEM with a nanoprobe) 1200 according to the third embodiment. FIG. 12 illustrates only the SEM with a nanoprobe 1200. However, as in FIG. 8, the computer system (including each of the control units) 830 that controls the SEM with a nanoprobe 1200 is connected thereto.

In addition to the configuration of the SEM system 801 of FIG. 8, the SME with a nanoprobe 1200 includes a nanoprobe 1201 and a nanoprobe control unit (not illustrated) that controls the nanoprobe 1201. By putting the nanoprobe 1201 on the gate hole 603, a signal is acquired from the drain hole 604 using the SEM. In the first embodiment, the signal of the drain hole 604 is measured by switching the irradiation position of the electron beam relative to the gate hole 603 and the drain hole 604. However, in the third embodiment, the nanoprobe 1201 is put on the gate hole 603 to apply a potential. A signal amount obtained in response to the second electron beam of the drain hole 604 at the potential is measured.

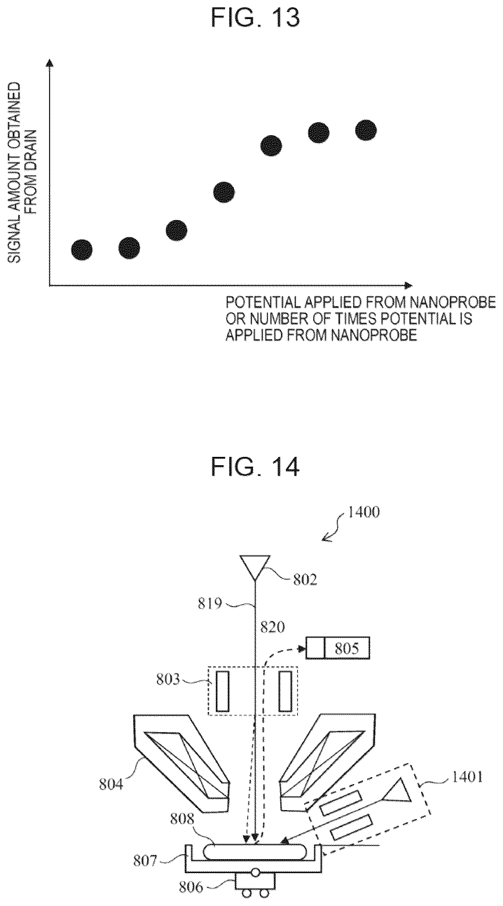

FIG. 13 is a diagram illustrating a relationship between the potential applied from the nanoprobe 1201 to the gate hole 603 and the signal amount obtained from the drain hole (nanoprobe potential-drain hole signal amount characteristics). In the characteristics of FIG. 13, in the case of a complete voltage source, electrons are not charged, and thus the horizontal axis represents the applied potential. On the other hand, when even a small amount of a current flows due to a minute leakage or the like, as in the output characteristics of the first embodiment, the horizontal axis represents the number of times the potential is applied from the nanoprobe 1201.

As described above, with the third embodiment, the same effects of as those of first embodiment can be expected. In addition, in the third embodiment, the potential is applied from the nanoprobe to the gate hole 603. Therefore, the electron beam irradiation does not need to switch between the gate and the drain. Therefore, a signal (observation image) can be continuously acquired from the drain hole 604.

### (4) Fourth Embodiment

In the first and second embodiments, the Tr is changed to the ON state (GATE/ON state) by irradiating the gate hole 603 with the first electron beam for charging and increasing the potential of the gate hole 603. On the other hand, in a fourth embodiment, the electrical characteristic measurement process is executed as in the first embodiment by adding a sub-electron optical system 1401.

FIG. 14 is a diagram illustrating a configuration example of a scanning electron microscope (SEM) 1400 including the sub-electron optical system 1401 according to the fourth embodiment. In FIG. 14, electron optical system components 802 to 804 will be referred to as a main electron optical system, and the added electron optical system will be referred to as the sub-electron optical system 1401.

FIG. 14 illustrates only the SEM 1400 including the sub-electron optical system 1401. However, as in FIG. 8, the computer system (including each of the control units) 830 that controls the scanning electron microscope (SEM) 1400 including the sub-electron optical system 1401 is connected thereto. In addition, the number of the sub-electron optical systems 1401 is not limited to one, and two or more sub-electron optical systems 1401 may be provided. Further, in FIG. 14, the sub-electron optical system 1401 is disposed to be seen between the objective lens 804 and the sample holder 807. However, by disposing the sub-electron optical system 1401 on the upper side as in the position of the electron gun 802, the deflector 803 or the objective lens 804 can be shared.

In the SEM 1400 including the sub-electron optical system 1401, the gate hole 603 is irradiated with an electron beam from the sub-electron optical system 1401, the drain hole 604 is irradiated with an electron beam from the main electron optical systems 802 to 804, and a signal is acquired from the drain hole 604.

In the fourth embodiment, since the irradiation position of the electron beam does not need to be switched, a signal (observation image) can be continuously acquired from the drain hole 604. In addition, the parameter of the sub-electron optical system 1401 can be set to a parameter different from the parameter of the main electron optical system. As a result, a signal change can be grasped based on the magnitude of the gate capacitance of the Tr or the structure similar to the Tr in the internal structure. For example, when the gate capacitance is small, a signal change can be grasped by reducing the probe current of the sub-electron optical system 1401. Conversely, when the gate capacitance is large, a signal change can be grasped by increasing the probe current of the sub-electron optical system 1401. This way, according to the fourth embodiment, the electrical characteristic measurement process can be smoothly executed based on the gate capacitance of the Tr or the structure similar to the Tr in the internal structure.

### (5) Fifth Embodiment

In the first and second embodiments, the drain hole 604 is irradiated with the second electron beam to obtain a signal. On the other hand, in a fifth embodiment, the drain hole 604 is irradiated with a pulsed beam instead of the second electron beam.

In the fifth embodiment, among signals (images) obtained by scanning a beam while changing beam conditions of the pulsed beam (the scan speed of the beam or the blocking time of the pulsed beam), a beam condition where the signal amount is the maximum is searched and used as an alternative to the second electron beam. As a result, when a change in the signal amount obtained by the irradiation of the second electron beam is small, a large signal can be acquired. That is, when the pulsed beam is used, a signal difference can be maximized. Therefore, the rising of the Tr characteristics can be advanced, and the resolution can be improved accordingly. Accordingly, when a change in brightness caused by the electron beam irradiation is not large, the change in brightness can be easily grasped by changing the electron beam to the pulsed beam.

### (6) Sixth Embodiment

In the first to fifth embodiments, the Tr is changed to the ON state (GATE/ON state) by irradiating the gate hole 603 with the electron beam for charging. However, when a pattern is charged, the charging of the pattern is maintained. Therefore, the measurement cannot be executed again.

Accordingly, in a sixth embodiment, the remaining charge is removed (erased) by adding a charge erase sequence using ultraviolet irradiation such that the measurement can be executed again. In addition, regarding a pattern that not measured at all, the pattern may be charged in a step immediately before executing the measurement during the semiconductor manufacturing process. Therefore, it is important to execute the charge erase sequence.

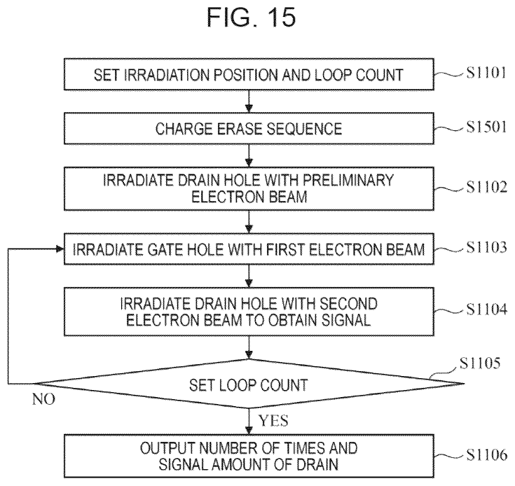

FIG. 15 is a flowchart illustrating the electrical characteristic measurement process according to the sixth embodiment. In the sixth embodiment, before irradiating the drain hole 604 with the preliminary electron beam to charge the drain hole 604, the charge erase sequence (S1501) is executed such that the electrical characteristic measurement process can be stably executed. As the charge erase sequence (S1501), the charge erase by ultraviolet irradiation can be applied. In this case, a method of uniformly irradiating the entire wafer with ultraviolet light or a method of irradiating a part of the wafer with ultraviolet light can be used. In order to implement the charge erase sequence, for example, an ultraviolet irradiation unit (not illustrated) may be provided in the SEM system 801 such that the computer system 830 controls the operation of the ultraviolet irradiation unit.

In the electrical characteristic measurement process (FIG. 11) according to the second embodiment, the charge erase sequence (S1501) may be executed before starting the irradiation (S102) of the gate hole 603 with the first electron beam.

### (7) Seventh Embodiment

In a seventh embodiment, a function of converting a relationship corresponding to the electrical characteristic measurement result and displaying the relationship based on the result of the first or second embodiment is provided. In the seventh embodiment, for example, the number of times the gate hole 603 is irradiated represented in the horizontal axis of FIG. 7 is converted into Vg of FIG. 5. Specifically, the number of times the gate hole 603 is irradiated corresponds to a charge Q in Expression Q=CV representing a capacitance. By repeating the number of times, the charge Q increases, whereas the potential V increases because the capacitance C is a fixed value. That is, the gate voltage Vg is obtained. Note that, in the SEM, since the entirety is irradiated with the electron beam, a portion other than the hole pattern is also affected by the potential such as charge. Therefore, it is necessary to combine the numerical values (scales) of the horizontal axis and the vertical axis through an experiment, a simulation, or the like.

On the other hand, when the signal amount obtained from the drain hole 604 of the vertical axis of FIG. 7 is converted into Ids of FIG. 5, as represented by a relational expression I=Q/At between a current and a charge, the state changes from a charged state, that is, a state where the charge Q remains to a state where the charge moves, that is, a state where the current I flows, and the signal amount and the drain-source current Ids are associated with each other. Note that conversion through an experiment or the like is necessary to calculate a specific numerical value of the charge Q from the signal amount obtained from the SEM. For example, by comparing characteristics where the signal amount obtained from the drain hole 604 is normalized by a maximum value and characteristics where the drain-source current Ids is normalized by a maximum value, the evaluation of a semiconductor (evaluation of whether a defect is present) may be executed.

As described above, the number of times the gate hole 603 is irradiated and the signal amount obtained by irradiating the drain hole 604 with the electron beam can be grasped as the Vg-Ids characteristics representing the Tr characteristics through the above-described conversion process, and the conversion result can be displayed and evaluated.

### (8) Conclusion

(i) In the charged particle beam system (for example, the SEM system 801) according to the first embodiment, the drain is irradiated and charged with the preliminary charged particle beam, the irradiation of the gate with the first charged particle beam and the irradiation of the drain with the second charged particle beam are alternately executed a given number of times of irradiation (multiple times), the information regarding the signal amount (for example, the brightness value, the number of photons, or the amount of secondary electrons) obtained from the drain is acquired, and the first electrical characteristic (refer to FIG. 7) representing the relationship of the signal amount obtained from the drain corresponding to the number of times of the irradiation of the gate is generated and output. The target (sample) of the process is a wafer in a process during a semiconductor manufacturing process, the wafer having an internal structure where a transistor or a structure similar to a transistor is provided. As a result, even regarding the wafer in an intermediate process of semiconductor manufacturing, the electrical characteristic corresponding to the Tr characteristics (gate voltage-source-drain current characteristics) can be acquired. In addition, by using the electrical characteristics, for example, whether a defect is present in the intermediate process of semiconductor manufacturing (at an early stage before a wiring process or a final process) can be evaluated without destructing the wafer.

The charging process with the preliminary charged particle beam is executed until the charge value in the drain is maximized (the image is the darkest: the brightness value is the minimum value). As a result, the shape of the Tr characteristics having the rising portion 504 (refer to FIG. 5) can be approximated to the shape of the electrical characteristics.

(ii) In the charged particle beam system according to the second embodiment, the wafer of the semiconductor element that becomes non-conductive by changing the Tr to the ON state is set as a processing target, the charging process of the drain with the preliminary charged particle beam is not executed, and the irradiation of the gate with the first charged particle beam and the irradiation of the drain with the second charged particle beam are alternately executed a given number of times of irradiation (multiple times) to acquire the information regarding the signal amount obtained from the drain. As in the first embodiment, the first electrical characteristic is acquired. This way, the appropriate electrical characteristic acquisition process for the type of the wafer can be executed.
(iii) The charged particle beam device 1200 in the charged particle beam system according to the third embodiment includes the probe (nanoprobe) 1201 configured to apply a potential (refer to FIG. 12). In the third embodiment, instead of irradiating the gate with the first charged particle beam, a potential is applied from the probe to the gate stepwise (multiple times) until the Tr is changed to the ON state. By applying a potential from the probe instead of irradiating the gate with the charged particle beam (for example, an electron beam), only the drain is irradiated with the charged particle beam. Therefore, the effect of simplifying the scanning control of the charged particle beam can be expected.
(iv) The charged particle beam device 1400 in the charged particle beam system according to the fourth embodiment includes not only the main optical system for irradiating the drain with the charged particle beam but also the sub-optical system for irradiating the gate with the charged particle beam. As a result, the probe current to be applied to the gate can be easily and smoothly adjusted based on the gate capacitance in the Tr or the structure similar to the Tr in the internal structure of the wafer.
(v) In the charged particle beam system according to the fifth embodiment, the drain is irradiated with the pulsed beam as the second charged particle beam. The condition of the pulsed beam where the signal amount obtained from the drain is the maximum can be searched. Therefore, the resolution of the image (brightness value) can be improved.
(vi) The charged particle beam system according to the sixth embodiment further includes the ultraviolet irradiation unit for the charge erase process. As a result, the electrical characteristic measurement process using the charged particle beam irradiation can start from the state where the wafer is stabilized.
(vii) In the charged particle beam system according to the seventh embodiment, the first electrical characteristic (refer to FIG. 7) representing the relationship of the signal amount obtained from the drain corresponding to the number of times of the irradiation of the gate are converted into the second electrical characteristic (refer to FIG. 5) representing the relationship of the drain-source current corresponding to the gate voltage, and the conversion result is output. Specifically, in the charged particle beam system, the value of the number of times of the irradiation of the gate with the first charged particle beam is converted into a value of the gate voltage based on the expression (charge Q=capacitance C×gate voltage V) representing a capacitance, and the value of the signal amount obtained from the drain is converted into a value of the drain-source current based on the relational expression (current I=charge Q/Δt) of a current and a charge. As a result, the second electrical characteristic (FIG. 5) is generated. As a result, the Vg-Ids characteristics that are a reference for the Tr of the measurement target and the first electrical characteristic (such as the characteristics of FIGS. 7, 10, and 13) obtained by the technique of the present disclosure can be easily compared, and the defect inspection of the wafer having the internal structure where the Tr or the structure similar to the Tr is provided can be executed at a stage during the semiconductor manufacturing process.
(viii) The functions of the present embodiments and each of the examples can also be implemented by a program code of software. In this case, a storage medium that records the program code is provided to a system or a device, and a computer (or a CPU or an MPU) in the system or the device reads the program code stored in the storage medium. In this case, the program code itself read from the storage medium implements the functions of the above-described embodiments, and the program code itself and the storage medium recording the program code configure the present disclosure. As the storage medium for supplying the program code, for example, a flexible disk, a CD-ROM, a DVD-ROM, a hard disk, an optical disk, a magneto-optical disk, a CD-R, a magnetic tape, a non-volatile memory card, or a ROM is used.

In addition, an OS (operating system) or the like that operates on the computer may execute some or all of the actual processes based on an instruction of the program code to implement the functions of the above-described embodiments through the processes. Further, after writing the program code read from the storage medium into a memory in the computer, a CPU or the like on the computer may execute some or all of the actual processes based on an instruction of the program code to implement the functions of the above-described embodiments through the processes.

Further, the program code of the software implementing the functions of the embodiment and each of the examples may be distributed via a network such that the program code is stored in storage means such as a hard disk or a memory of a system or a device or in a storage medium such as a CD-RW or a CD-R and a computer (or a CPU or an MPU) in the system or the device reads and executes the program code stored in the storage means or the storage medium during use.

The process and the technique described herein does not essentially relate to any specific device, and can also be implemented by any combination of components. In addition, various types of general-purpose devices can be added. In order to execute the functions of the present embodiment and each of the examples, a dedicated device may also be constructed. In addition, various functions can be formed by appropriately combining the plurality of components disclosed in the present embodiment and each of the examples. For example, some components may be removed from all the components disclosed in the embodiment and each of the examples, or components of different examples may be appropriately combined.

In the present disclosure, the specific examples have been described. However, these examples do not limit the present disclosure from all the viewpoints and are for description purpose (to understand the technique according to the present disclosure). It can be understood by those having common knowledge in the present technical field that the technique of the present disclosure can be implemented by multiple combinations of suitable hardware, software, and firmware. In addition, the described software can be implemented in a wide range of programs or script languages such as assembler, C/C++, perl, Shell, PHP, and Java (registered trade mark).

Further, in the above-described embodiments, the drawings illustrate control lines and information lines as considered necessary for descriptions but do not illustrate all control lines or information lines in the products. All the configurations may be interconnected.

Further, it is obvious that those having common knowledge in the present technical field can implement other embodiments of the present disclosure in consideration of the present embodiment and each of the examples. The specification and the specific examples are merely typical examples, and the scope and concepts of the present disclosure are indicated by the following claims.

### REFERENCE SIGNS LIST

101: SEM image

102, 103, 104: contact hole

201: internal structure

202: Si substrate area

203: gate electrode

301: cross-sectional structure

401: equivalent circuit

402: source

403: gate

404: drain

405: MOS transistor

406: GND

407: variable voltage

408: fixed voltage

409, 503: drain-source current Ids

501: Vg-Ids characteristics

502: gate voltage Vg

504: rising portion of Tr characteristics (Vg-Ids characteristics)

602: source hole

603: gate hole

604: drain hole

605: first electron beam

606: second electron beam

606′: preliminary electron beam

701: relationship (characteristics) 701 between number of times of irradiation of gate hole 603 with electron beam (horizontal axis) and signal amount obtained from drain hole 604 (vertical axis)

801: SEM system

802: electron gun

803: deflector

804: objective lens

805: detector

806: XYZ stage

807: sample holder

808: sample

809: electron gun control unit

810: deflection signal control unit

811: objective lens coil control unit

812: detector control unit

813: XYZ stage control unit

814: master clock control unit

815: detection signal processing unit

816: image forming unit

817: analysis and display unit

818: control parameter setting and overall control unit

819: electron beam

820: secondary electron

830: computer system

1200: scanning electron microscope with nanoprobe

1201: nanoprobe

1400: scanning electron microscope including sub-electron optical system

1401: sub-electron optical system

1. A charged particle beam system comprising:
a charged particle beam device configured to irradiate a sample with a charged particle beam to acquire a signal from the sample; and
a computer system configured to control an operation of the charged particle beam device,
wherein the sample is a wafer in a process during a semiconductor manufacturing process, the wafer having an internal structure where a transistor or a structure similar to a transistor is provided, and
the computer system executes
a process of setting given information to the charged particle beam device, the given information including at least information regarding the number of times a gate and a drain of the internal structure are irradiated with the charged particle beam and information regarding an irradiation position of the charged particle beam,
a process of controlling the charged particle beam device to execute irradiation of the gate with a first charged particle beam and irradiation of the drain with a second charged particle beam that is the same as or different from the first charged particle beam and acquiring information regarding a signal amount obtained from the drain by the irradiation of the second charged particle beam,
a process of generating a first electrical characteristic representing a relationship of the signal amount obtained from the drain corresponding to the number of times the gate is irradiated with the first charged particle beam, and
a process of outputting the first electrical characteristic.

2. The charged particle beam system according to claim 1,
wherein after controlling the charged particle beam device to irradiate the drain with a preliminary charged particle beam for charging, the computer system controls the charged particle beam device to alternately execute the irradiation of the gate with the first charged particle beam and the irradiation of the drain with the second charged particle beam and acquires the information regarding the signal amount obtained from the drain.

3. The charged particle beam system according to claim 2,
wherein the computer system controls the charged particle beam device to charge the drain with the preliminary charged particle beam as much as possible.

4. The charged particle beam system according to claim 2,
wherein the preliminary charged particle beam, the first charged particle beam, and the second charged particle beam are the same charged particle beam.

5. The charged particle beam system according to claim 1,
wherein the computer system controls the charged particle beam device to repeat the irradiation of the gate with the first charged particle beam and the irradiation of the drain with the second charged particle beam three or more times in response to the information regarding the number of times of the irradiation.

6. The charged particle beam system according to claim 1,
wherein the computer system acquires a brightness value, the number of photons, or an amount of secondary electrons as the signal amount obtained from the drain.

7. The charged particle beam system according to claim 1,
wherein the charged particle beam device irradiates the drain with an electron beam or a pulsed beam as the second charged particle beam.

8. The charged particle beam system according to claim 1,
wherein the charged particle beam device includes an ultraviolet irradiation unit, and
the computer system controls the charged particle beam device to irradiate the wafer with ultraviolet light from the ultraviolet irradiation unit before executing the irradiation of the gate with the first charged particle beam and the irradiation of the drain with the second charged particle beam, and erases charge in the wafer.

9. The charged particle beam system according to claim 2,
wherein the charged particle beam device includes an ultraviolet irradiation unit, and
the computer system controls the charged particle beam device to irradiate the wafer with ultraviolet light from the ultraviolet irradiation unit before executing the irradiation of the drain with the preliminary charged particle beam, and erases charge in the wafer.

10. The charged particle beam system according to claim 1,
wherein the computer system converts the first electrical characteristic into a second electrical characteristic representing a relationship of a drain-source current corresponding to a gate voltage and outputs the second electrical characteristic.

11. The charged particle beam system according to claim 10,
wherein the computer system generates the second electrical characteristic by converting a value of the number of times of the irradiation of the gate with the first charged particle beam into a value of the gate voltage based on an expression representing a capacitance and converting a value of the signal amount obtained from the drain into a value of the drain-source current based on a relational expression of a current and a charge.

12. The charged particle beam system according to claim 1,
wherein the charged particle beam device includes a probe configured to apply a potential, and
the computer system controls the charged particle beam device to apply a potential from the probe to the gate instead of irradiating the gate with the first charged particle beam.

13. The charged particle beam system according to claim 12,
wherein the computer system continuously acquires a signal from the drain by continuously irradiating the drain with the second charged particle beam.

14. The charged particle beam system according to claim 1,
wherein the charged particle beam device includes a main optical system for irradiating the wafer with the second charged particle beam and at least one sub-optical system for irradiating the wafer with the first charged particle beam.

15. The charged particle beam system according to claim 14,
wherein the computer system continuously acquires a signal from the drain by controlling the main optical system to continuously irradiate the drain with the second charged particle beam.

16. The charged particle beam system according to claim 1,
wherein the computer system acquires the information regarding the irradiation position of the charged particle beam from CAD data of the wafer.

17. A sample evaluation information generation method of generating information for evaluating a sample by allowing a computer system to control a charged particle beam device that irradiates the sample with a charged particle beam to acquire a signal from the sample,
the sample being a wafer in a process during a semiconductor manufacturing process and having an internal structure where a transistor or a structure similar to a transistor is provided, and
the sample evaluation information generation method comprising:
allowing the computer system to set given information to the charged particle beam device, the given information including at least information regarding the number of times a gate and a drain of the internal structure are irradiated with the charged particle beam and information regarding an irradiation position of the charged particle beam;
allowing the computer system to control the charged particle beam device to alternately execute irradiation of the gate with a first charged particle beam and irradiation of the drain with a second charged particle beam that is the same as or different from the first charged particle beam;
allowing the computer system to acquire information regarding a signal amount obtained from the drain by the irradiation of the second charged particle beam after the irradiation of the first charged particle beam;
allowing the computer system to repeat the alternate execution of the irradiation of the gate with the first charged particle beam and the irradiation of the drain with the second charged particle beam and the acquisition of the information regarding the signal amount obtained from the drain by the irradiation of the second charged particle beam after the irradiation of the first charged particle beam multiple times; and
allowing the computer system to generate a first electrical characteristic representing a relationship of the signal amount obtained from the drain corresponding to the number of times the gate is irradiated with the first charged particle beam.

18. The sample evaluation information generation method according to claim 17, further comprising allowing the computer system to control the charged particle beam device to irradiate the drain with a preliminary charged particle beam for charging before the alternate execution of the irradiation of the gate with the first charged particle beam and the irradiation of the drain with the second charged particle beam.

19. The sample evaluation information generation method according to claim 18,
wherein the computer system controls the charged particle beam device to charge the drain with the preliminary charged particle beam as much as possible.
